(19) United States
(12) Patent Application Publication
(10) Pub. No.: US 2017/0020030 A1
(43) Pub. Date: Jan. 19, 2017

(54) Electronic Apparatus

(71) Applicant: COMPAL BROADBAND NETWORKS INC., Taipei City (TW)

(72) Inventors: Cheng-Shan Lin, Hsinchu County (TW); Chung-Ming Pan, Hsinchu County (TW)

(21) Appl. No.: 15/164,895

(22) Filed: May 26, 2016

Related U.S. Application Data
(60) Provisional application No. 62/193,099, filed on Jul. 16, 2015.

(30) Foreign Application Priority Data
Dec. 3, 2015 (TW) 104219410

(51) Int. Cl. H05K 7/20; H05K 7/18

(52) U.S. Cl. CPC H05K 7/20145; H05K 7/186; H04W 88/08

(57) ABSTRACT

An electronic apparatus for processing a network communication operation includes a covering module including a lighting unit and at least one input unit; a base module including a heat-dissipation unit; a plurality of vertical electronic modules; a frame module including a plurality of connecting units for connecting the covering module and the base module to form a trapezoid column body, and the plurality of vertical electronic modules disposed to an edge of the trapezoid column body to form a column-shape wind channel; and a housing configured to cover the column-shape wind channel for protecting the plurality of vertical electronic modules.

### CROSS REFERENCE TO RELATED APPLICATIONS

This application claims the benefit of both U.S. Provisional Application No. 62/193,099, filed on Jul. 16, 2015 and entitled “The structure design of new product”, the contents of which are incorporated herein.

### BACKGROUND OF THE INVENTION

1. Field of the Invention

The present invention relates to an electronic apparatus having a plurality of vertical configuration electronic modules, and more particularly, to an electronic apparatus having a plurality of vertical configuration electronic modules to forma column-shape wind tunnel for effectively dissipating heat of the electronic apparatus.

2. Description of the Prior Art

For the sake of comfortable operations for users and fitting different living/working circumstances, exterior appearances of many electronic apparatuses are designed to approach a simplified structure. Conventionally, some internal electronic elements inside the electronic apparatus, such as circuit boards, antennas, dissipating elements, are configured in a planar layout. However, the planar layout for a vertically configured/arranged electronic apparatus may result in a waste of internal space and a poor design for dissipating heat circulating inside the electronic apparatus.

Under such circumstances, it has become an important issue to provide another layout/design having better internal space utilization and heat dissipation for the vertically configured/arranged electronic apparatus, and to maintain proper functional operation and protection of the electronic apparatus.

### SUMMARY OF THE INVENTION

Therefore, the primary objective of the present invention is to provide an electronic apparatus having a plurality of vertical composition modules to form a column-shape wind channel for effectively dissipating heat of the electronic apparatus.

The present invention discloses an electronic apparatus for processing a network communication operation. The electronic apparatus comprises a covering module, comprising a lighting unit and at least one input unit; a base module, comprising a heat-dissipation unit; a plurality of vertical electronic modules; a frame module, comprising a plurality of connecting units for connecting the covering module and the base module to forma trapezoid column body, and the plurality of vertical electronic modules being disposed to an edge of the trapezoid column body to forma column-shape wind channel; and a housing, configured to cover the column-shape wind channel for protecting the plurality of vertical electronic modules.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 illustrates an external schematic diagram of an electronic apparatus according to an embodiment of the invention.

FIG. 2 illustrates a local schematic diagram of a covering module of an electronic apparatus shown in FIG. 1.

FIG. 3 illustrates an assembling schematic diagram of a covering module shown in FIG. 2.

FIG. 4 illustrates a local schematic diagram of a base module of an electronic apparatus shown in FIG. 1.

FIG. 5 illustrates an assembling schematic diagram of a base module shown in FIG. 4.

FIG. 6 illustrates a local schematic diagram of a frame module of an electronic apparatus shown in FIG. 1.

FIG. 7 illustrates an assembling schematic diagram of a base module shown in FIG. 4 combining with a frame module shown in FIG. 6.

FIG. 8 illustrates an assembling schematic diagram of a trapezoid column body combining with a plurality of vertical electronic modules according to an embodiment of the invention.

FIG. 9 illustrates a schematic diagram of a backboard of an electronic apparatus shown in FIG. 1.

FIG. 10 illustrates an assembling schematic diagram of a column-shape wind tunnel shown in FIG. 7 combining with a backboard shown in FIG. 9.

FIG. 11 illustrates an assembling schematic diagram of a column-shape wind tunnel shown in FIG. 10 combining with an antenna carrier module.

FIG. 12 illustrates a schematic diagram of an antenna unit of an electronic apparatus shown in FIG. 1.

FIG. 13 illustrates an assembling schematic diagram of a column-shape wind tunnel shown in FIG. 11 combining with a housing.

### DETAILED DESCRIPTION

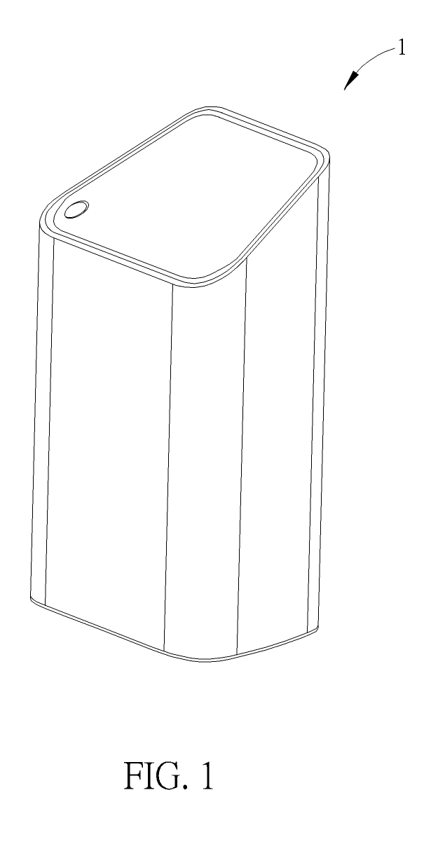

Please refer to FIG. 1, which illustrates an external schematic diagram of an electronic apparatus 1 according to an embodiment of the invention. The electronic apparatus 1 comprises a plurality of composition modules, and preferably, is a cable modem with a wireless-access-point function to process a network communication operation (e.g. a wired communication operation or a wireless communication operation). In comparison with the prior art that some internal electronic elements, such as circuit boards, antennas, dissipating elements, being configured in the planar layout, the embodiment of the invention applies a vertical configuration layout to dispose the plurality of electronic modules inside the electronic apparatus 1, so as to effectively improve an internal space utilization rate inside the electronic apparatus 1 and a heat dissipation of the electronic apparatus 1. More detailed descriptions will be presented in the following paragraphs.

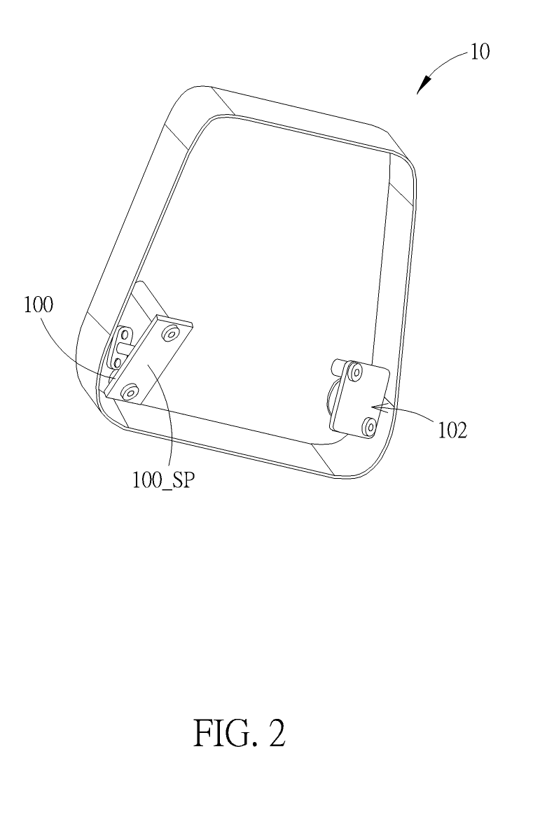

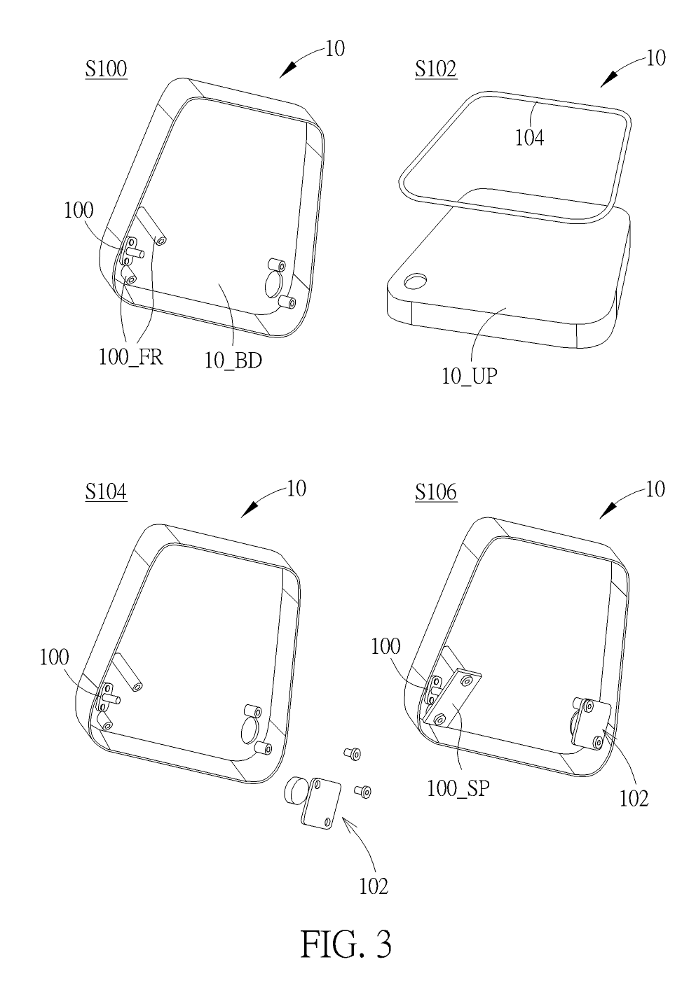

Please refer to FIG. 2 and FIG. 3, wherein FIG. 2 illustrates a local schematic diagram of a covering module 10 of the electronic apparatus 1 shown in FIG. 1, and FIG. 3 illustrates an assembling schematic diagram of the covering module 10 shown in FIG. 2. As shown in FIG. 2 and FIG. 3, the covering module 10 of the embodiment comprises a lighting unit 100 and at least one input unit 102. The number of the input unit 102 can be adaptively adjusted, and hereinafter, only one input unit 102 is depicted in the embodiment, which is not limiting the scope of the invention. The lighting unit 100 is utilized to generate an instruction signal to tell the user whether the electronic apparatus 1 has been initiated or not, and the lighting unit 100 can generate different colors or different flashing frequencies for representing different operational modes of the electronic apparatus 1. Besides, the input unit 102 can be configured to process an initiation operation of the electronic apparatus 1. For example, the input unit 102 can be a power button, and the electronic apparatus 1 can be correspondingly initiated after the user has pressed the power button. Considering aesthetic designs of the electronic apparatus 1, the covering module 10 of the embodiment is not horizontally configured, i.e. the covering module 10 has an inclination configuration angle and is configured on an oblique plane of the electronic apparatus 1. In addition, an external surface 10_UP of the covering module 10 of the embodiment has a transparent protection cover 104 to protect and attach on the external surface 10_UP of the covering module 10. Further, the transparent protection cover 104 can print a watermark thereon to increase the aesthetic designs of the electronic apparatus 1.

The covering module 10 can be assembled by steps shown in FIG. 3. In step S100, dispose the lighting unit 100 onto a main housing 10_BD of the covering module 10 via a fusing fixing way, and dispose fixing holders 100_FR nearby the lighting unit 100. In step S102, attach the transparent protection cover 104 on the external surface 10_UP of the covering module 10. In step S104, utilize a screw (e.g. a screw with the type as M3_L5) to fix the input unit 120 onto the main housing 10_BD of the covering module 10. In step S106, utilize the screw with the type as M3_L5 to fix a fixing plate 100_SP on the fixing holders 100_FR for firmly fixing the lighting unit 100, so as to finish the assembling of the covering module 10.

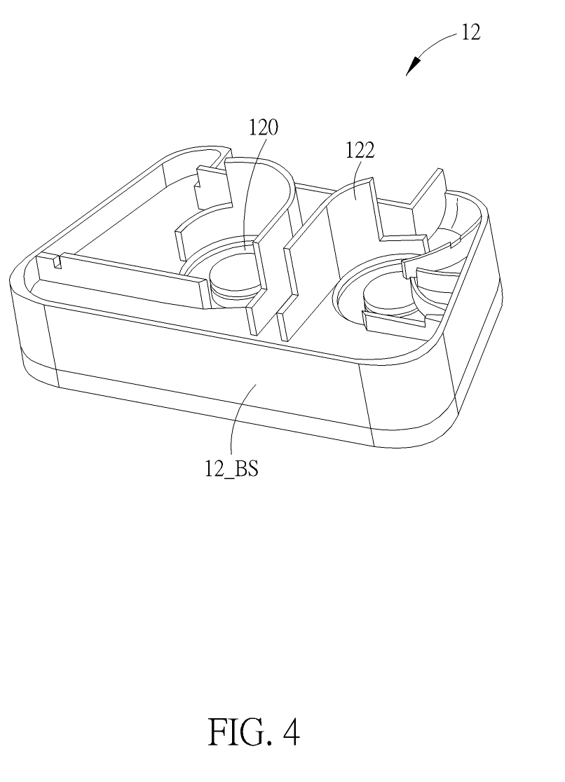

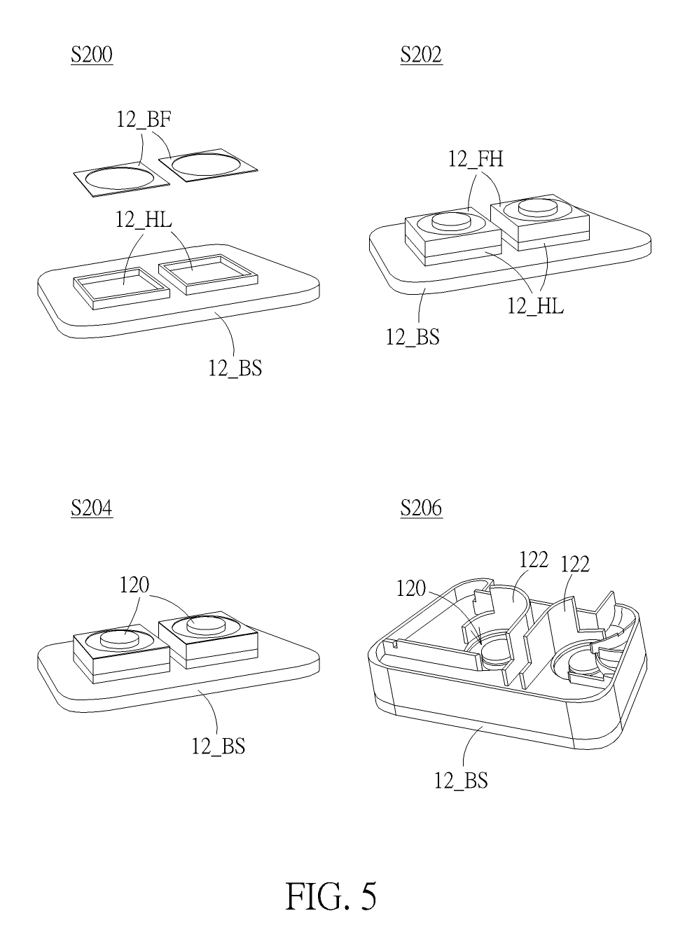

Please refer to FIG. 4 and FIG. 5, wherein FIG. 4 illustrates a local schematic diagram of a base module 12 of the electronic apparatus 1 shown in FIG. 1, and FIG. 5 illustrates an assembling schematic diagram of the base module 12 shown in FIG. 4. As shown in FIG. 4 and FIG. 5, the base module 12 of the embodiment comprises two heat-dissipation units 120 and a current-conduction unit 122. Each heat-dissipation unit 120 comprises a fan, and a vane of the fan is configured to inhale a low-temperature air. The current-conduction unit 122 is disposed on the top of the heat-dissipation unit 122 to cover the two heat-dissipation units 120 and form a vertical current-conduction plate. Under such circumstances, the current-conduction units 122 are configured to conduct the low-temperature air inhaled by the heat-dissipation unit 120 as a vertical conduction air, so as to assist a heat dissipation of the electronic apparatus 1. Certainly, the number and the configuration position of the heat-dissipation unit 120 and the current-conduction unit 122 can be adaptively adjusted in view of different requirements, which is not limiting the scope of the invention. Besides, the base module 12 of the embodiment further comprises an anti-proof unit to be disposed at a bottom plane of the base module 12, so as to improve an anti-proof effect of the electronic apparatus 1 being vertically configured.

The base module 12 can be assembled by steps shown in FIG. 5, and a base 12_BS of the base module 12 comprises two holes 12_HL. In step S200, dispose two elastic pads 12_BF inside the two holes 12_HL. In step S202, separately dispose two dissipation unit housings 12_FH on the two elastic pads 12_BF around the two holes 12_HL. In step S204, separately dispose two heat-dissipation units 120 (i.e. the fans) at the two dissipation unit housings 12_FH. In step S206, dispose the current-conduction unit 122 at the base 12_BS to finish the assembling of the base module 12.

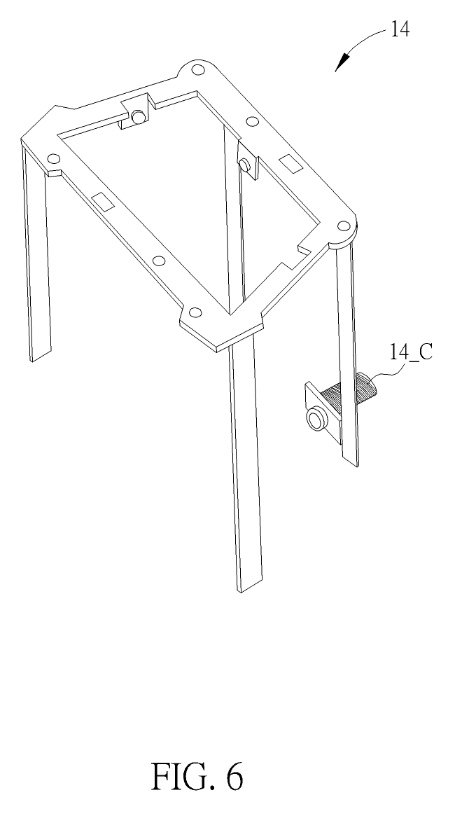

Please refer to FIG. 6, which illustrates a local schematic diagram of a frame module 14 of the electronic apparatus 1 shown in FIG. 1. As shown in FIG. 6, the frame module 14 of the embodiment is a hollow holder and comprises a plurality of connecting units, and a plurality of holes are disposed on the connecting units for combining a variety of functional composition modules/units. As a whole, the frame module 14 is regarded as a quadrilateral from a top view and as a prism from a side view. The material of the frame module 14 can choose the metal material or the nonmetal material, which is not limiting the scope of the invention. Preferably, the frame module 14 of the embodiment is a symmetrical trapezoid column body, and those skilled in the art can adaptively dispose at least one connecting unit/module onto the frame module 14 via a mechanical pressing, fixing, or locking way according to different practical requirements, such that the frame module 14 can be connected with different connecting units/modules for different applications. Besides, the frame module 14 of the embodiment further comprises an alternating-current (AC) direct-current (DC) connecter 14_C to be disposed at a side bottom of the frame module 14 for connecting with a power supply module.

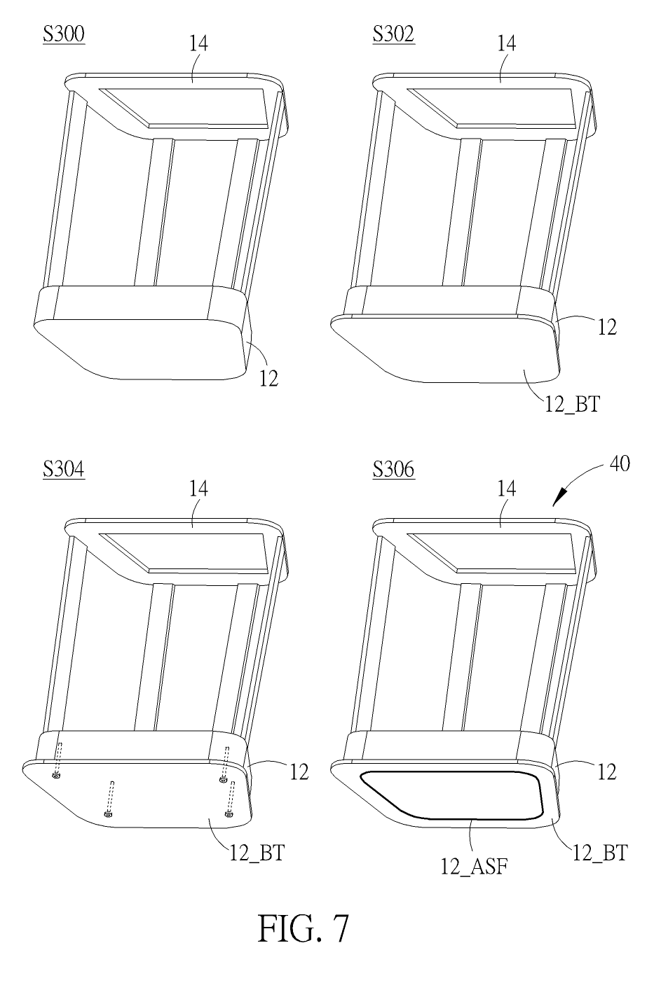

Please refer to FIG. 7, which illustrates an assembling schematic diagram of the base module 12 shown in FIG. 4 combining with the frame module 14 shown in FIG. 6. In step S300, dispose the frame module 14 onto the base module 12. In step S302, dispose a base stand 12_BT on the base module 12. In step S304, utilize a screw (e.g. a screw with the type as M3_L30) to firmly fix the base module 12, the frame module 14 and the base stand 12_BT. In step S306, attach an anti-proof unit 12_ASF on the base stand 12_BT to improve an anti-proof effect of the electronic apparatus 1 being vertically configured. Accordingly, the assembling of the base module 12 and the frame module 14 is finished to form a trapezoid column body 40.

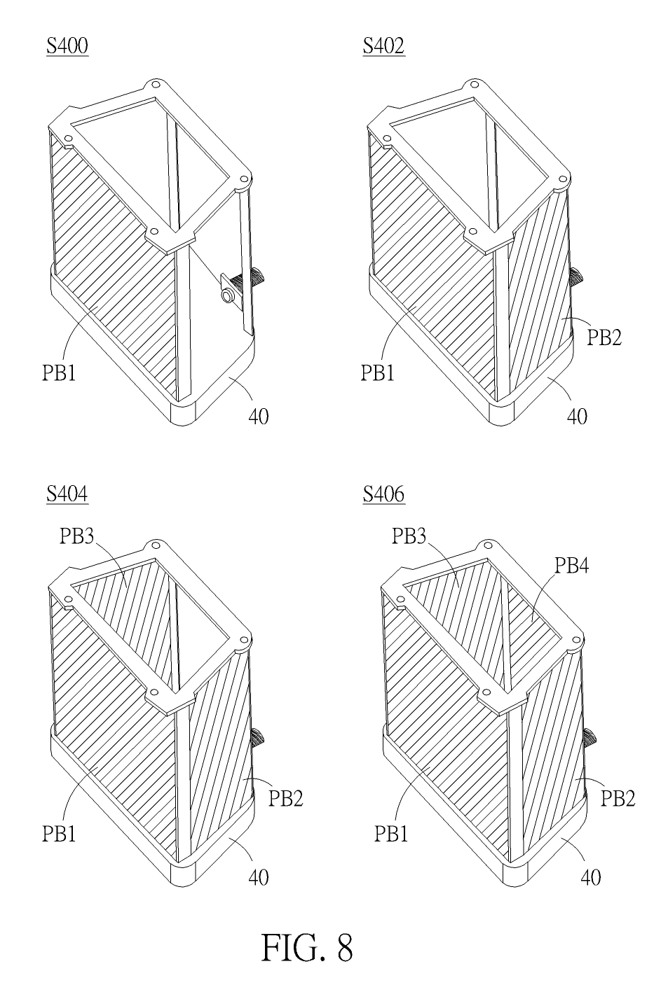

Under such circumstances, the embodiment of the invention has the base module 12 and the frame module 14 to be the trapezoid column body 40, and a plurality of vertical electronic modules are correspondingly disposed at an edge of the trapezoid column body 40, i.e. the edge of the frame module 14 has a plurality of fixing fillisters to firmly fix the plurality of vertical electronic modules for surrounding the trapezoid column body 40 as a column-shape wind tunnel. For example, please refer to FIG. 8, which illustrates an assembling schematic diagram of the trapezoid column body 40 combining with a plurality of vertical electronic modules PB1, PB2, PB3 and PB4. As shown in FIG. 8, utilize screws (e.g. screws with the type as M3_L5) to fix the vertical electronic module PB1, the vertical electronic module PB2, the vertical electronic module PB3 and the vertical electronic module PB4, respectively, at four sides of the trapezoid column body 40, so as to form a column-shape wind tunnel 50.

Preferably, the vertical electronic modules PB1, PB2, PB3 and PB4 of the embodiment are printed circuit boards, and each vertical electronic module is configured to process different operations. For example, the vertical electronic modules PB1, PB2, PB3 and PB4 can individually dispose at least one of a processing module, a memory module, a cable data processing module, a wireless signal communication module, a wireless signal processing module and an input-output controlling module, such that the electronic apparatus 1 can process the network communication operation. Conventionally, the printed circuit boards comprise a plurality of non-planer composition modules/units and the planar layout for the vertically configured electronic apparatus may result in a waste of internal space. In comparison, the embodiment of the invention provides the electronic apparatus 1 to form the vertically configured trapezoid column body and to have the hollow column structure. Also, the embodiment of the invention has the printed circuit boards surrounding four sides of the trapezoid column body, such that an available utilization area of each electronic module is correspondingly increased. In other words, the plurality of non-planer composition modules/units on the printed circuit boards can all be disposed inside the hollow column structure without structurally overlapping or colliding.

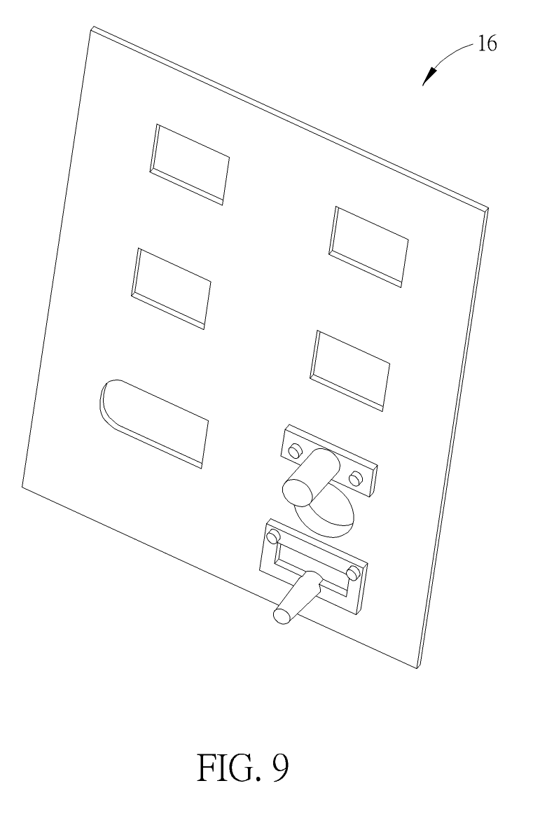

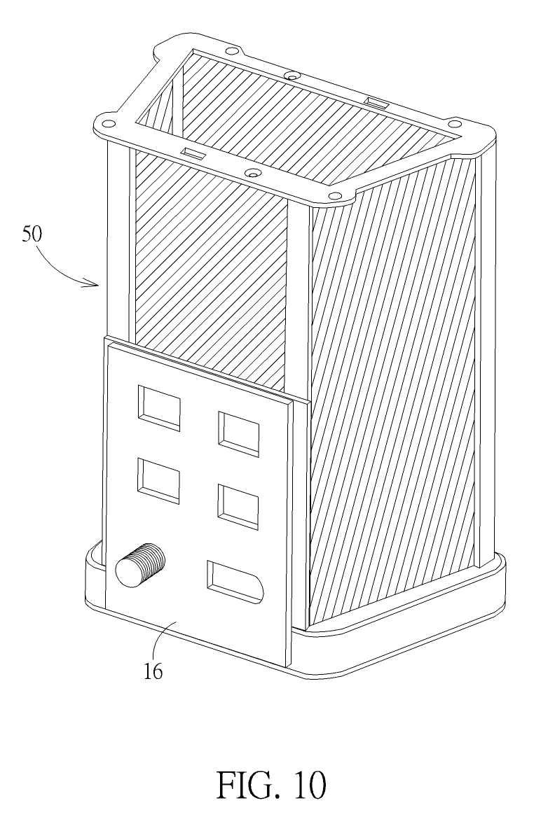

Please refer to FIG. 9, which illustrates a schematic diagram of a backboard 16 of the electronic apparatus 1 shown in FIG. 1. As shown in FIG. 9, the backboard 16 of the embodiment comprises a plurality of holes to configure a plurality of signal lines of the vertical electronic modules inside the electronic apparatus 1 for transmitting different signals. Please refer to FIG. 10, which illustrates an assembling schematic diagram of the column-shape wind tunnel 50 shown in FIG. 7 combining with the backboard 16 shown in FIG. 9. As shown in FIG. 10, the plurality of connecting units of the frame module 14 comprise a plurality of holes to correspondingly fix the backboard 16, and the position of the backboard 16 can be designed to fit the configuration position of the plurality of transmission lines of the vertical electronic modules, such that the transmission lines can appropriately pass through the plurality of holes of the backboard 16 to prevent from being bent with structural damages.

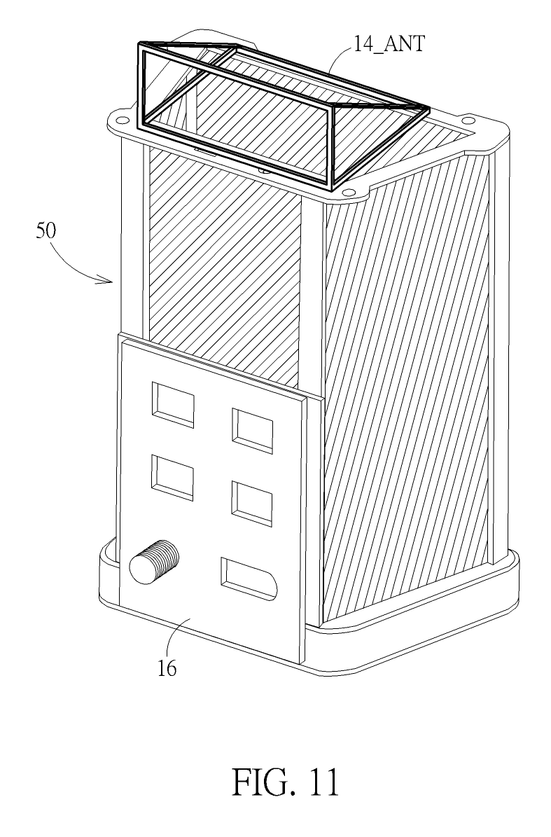

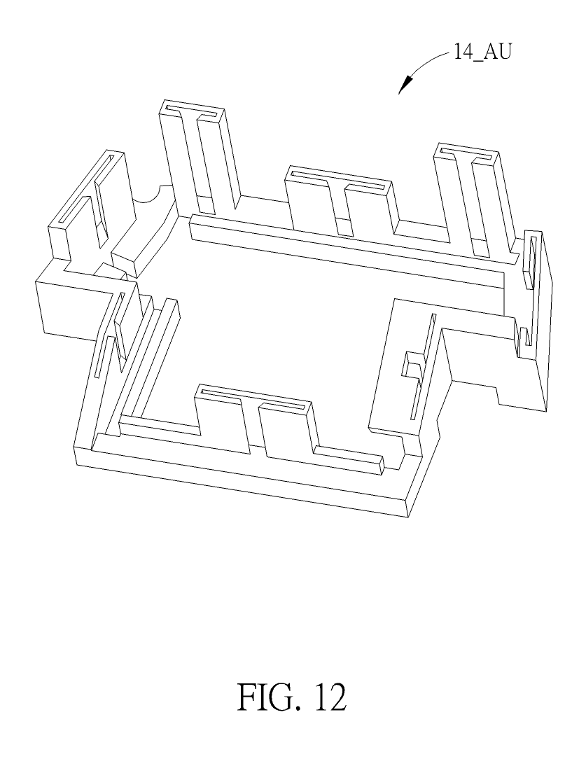

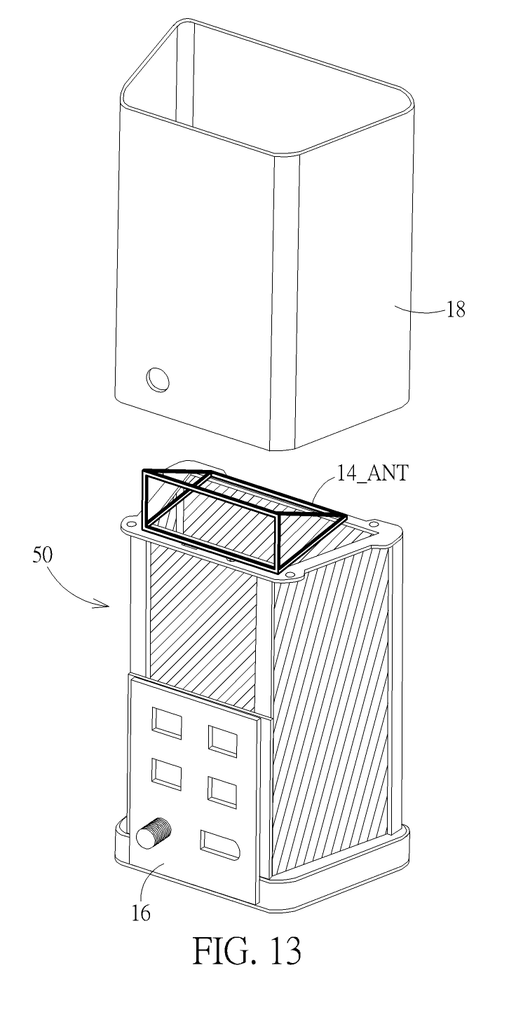

Please refer to FIG. 11, which illustrates an assembling schematic diagram of the column-shape wind tunnel 50 shown in FIG. 10 combining with an antenna carrier module 14_ANT. As shown FIG. 11, an upper plane of the column-shape wind tunnel 50 of the embodiment configures a plurality of antenna units, and the screws with the type as M3_L5 are utilized to fix the antenna carrier module 14_ANT and the frame module 14. The antenna units 14_AU of the embodiment are depicted in FIG. 12 to be firmly fixed on the antenna carrier module 14_ANT. Please refer to FIG. 13, which illustrates an assembling schematic diagram of the column-shape wind tunnel 50 shown in FIG. 11 combining with a housing 18. As shown in FIG. 13, after the antenna carrier module 14_ANT is fixed with the frame module 14, the housing 18 of the embodiment can be utilized to annularly cover the column-shape wind tunnel 50, so as to protect and shield the plurality of vertical electronic modules (i.e. wrapping four sides of the column-shape wind tunnel 50). Lastly, the covering module 10 is disposed on the top of the antenna carrier module 14_ANT and the frame module 14, so as to finish the assembling of the electronic apparatus 1. Besides, the housing 18 of the embodiment further configures at least one heat-dissipation hole to conduct an air corresponding to the heat-dissipation unit 120, so as to adaptively expel the heat inside the electronic apparatus 1.

Noticeably, the covering module 10, the base module 12 and the frame module 14 of the embodiment are configured to form the trapezoid column body, and certainly, those skilled in the art can adaptively adjustor change the trapezoid structure to be other structures, such as a triangular prism, a rectangular prism or other polyhedral prisms, for configuring the plurality of vertical electronic modules around the edge of the frame body 14, so as to maintain the column-shape wind tunnel for assisting the heat dissipation of the electronic apparatus 1, which is also within the scope of the invention.

In summary, the embodiments of the invention provide an electronic apparatus having a plurality of composition modules. By combining the covering module, the base module and the frame module to form the trapezoid column body and surrounding the plurality of vertical electronic modules to form the column-shape wind tunnel, the available utilization area of the vertical electronic modules can be effectively increased and the heat dissipation of the electronic apparatus can also be largely improved, such that the application range of the electronic apparatus can be significantly enlarged with better protection.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An electronic apparatus for processing a network communication operation, the electronic apparatus comprising:
a covering module, comprising a lighting unit and at least one input unit;
a base module, comprising a heat-dissipation unit;
a plurality of vertical electronic modules;
a frame module, comprising a plurality of connecting units for connecting the covering module and the base module to form a trapezoid column body, and the plurality of vertical electronic modules being disposed to an edge of the trapezoid column body to form a column-shape wind channel; and
a housing, configured to cover the column-shape wind channel for protecting the plurality of vertical electronic modules.

2. The electronic apparatus of claim 1, wherein the covering module has an inclination configuration angle corresponding to a horizontal plane, and an external surface of the covering module has a transparent protection cover.

3. The electronic apparatus of claim 1, wherein the lighting unit is utilized to generate an instruction signal, and the at least one input unit is utilized to process an initiation operation of the electronic apparatus.

4. The electronic apparatus of claim 1, wherein the base module further comprises a current-conduction unit, the heat-dissipation unit is a fan configured to inhale a low-temperature air, which forms a vertical conduction air via the current-conduction unit, so as to assist a heat dissipation of the electronic apparatus.

5. The electronic apparatus of claim 1, wherein the base module further comprises an anti-proof unit disposed at a bottom plane of the base module to improve an anti-proof effect of the electronic apparatus.

6. The electronic apparatus of claim 1, wherein the plurality of vertical electronic modules are a plurality of printed circuit boards and surround the trapezoid column body.

7. The electronic apparatus of claim 1, wherein the frame module comprises an antenna carrier module to configure a plurality of antenna units.

8. The electronic apparatus of claim 1, wherein the frame module comprises an alternating-current (AC) direct-current (DC) connecter to be disposed at a side bottom of the frame module.

9. The electronic apparatus of claim 1, wherein the frame module connects to a backboard, which comprises a plurality of holes to configure a plurality of signal lines.

10. The electronic apparatus of claim 1, wherein the housing comprises at least one heat-dissipation hole to conduct an air corresponding to the heat-dissipation unit.
